(19) United States
(12) Patent Application Publication
(10) Pub. No.: US 2012/0080065 A1
(43) Pub. Date: Apr. 5, 2012

(54) Thin Film Photovoltaic Modules with Structural Bonds

(75) Inventors: Todd Krajewski, Mountain View, CA (US); Donald S. Nelson, San Ramon, CA (US)

(73) Assignee: MIASOLE, Santa Clara, CA (US)

(21) Appl. No.: 12/894,736

(22) Filed: Sep. 30, 2010

(51) Int. Cl. H01L 31/042; H01L 21/98

(52) U.S. Cl. 136/244; 438/66; 257/E21.705

(57) ABSTRACT

Provided are novel photovoltaic module structures and related fabrication techniques. According to various embodiments, the structures include a structural bond related between two sealing sheets of the photovoltaic module configured to support one sealing sheet with respect to the other and, in certain embodiments, to support photovoltaic cells with respect to both sealing sheets. In certain embodiments, a photovoltaic module is fabricated without a back encapsulant layer, and the back sealing sheet is supported by the structural bond. The structural bond may also be used as a moisture barrier in addition or instead of an edge seal. The structural bond material can include a silicone-based polymer, which provides good adhesive and UV resistance properties. The structural bond may be formed by a structural bonding material that is dispensed around the photovoltaic cells.

### BACKGROUND

Photovoltaic cells are widely used for electricity generation by the photovoltaic effect, with multiple photovoltaic cells interconnected in module assemblies. These modules may in turn be arranged in arrays for large-scale conversion of solar energy into electricity. Photovoltaic cells are typically protected inside modules by two sealing sheets, a front transparent sealing sheet and a back sealing sheet. Glass plates are often used as sealing sheets. Conventional modules also include encapsulant and/or sealing materials to prevent moisture ingress.

Certain photovoltaic cell fabrication processes involve depositing thin film materials on a substrate to form a light absorbing layer sandwiched between electrical contact layers. The front or top contact is a transparent and conductive layer for current collection and light enhancement, the light absorbing layer is a semiconductor material, and the back contact is a conductive layer to provide electrical current throughout the cell. In one example of a fabrication process, a metallic back electrical contact layer is deposited on a substrate. A p-type semiconductor layer is then deposited on the back contact electrical contact layer and an n-type semiconductor layer is deposited on the p-type semiconductor layer to complete a p-n junction. Any suitable semiconductor materials, such as CIGS, CIS, CdTe, CdS, ZnS, ZnO, amorphous silicon, polycrystalline silicon, etc. may be used for these layers. A top transparent electrode layer is then deposited on the p-n junction. This layer may be a conductive oxide or other conductive film and is used for current collection. Once these or other materials have been deposited on the substrate to form a photovoltaic stack, the substrate and thin film materials deposited on it are cut into cells. Multiple cells are then assembled into a solar module together with materials listed above.

### SUMMARY

Provided are novel photovoltaic module structures and related fabrication techniques. According to various embodiments, the structures include a structural bond related between two sealing sheets of the photovoltaic module configured to support one sealing sheet with respect to the other and, in certain embodiments, to support photovoltaic cells with respect to both sealing sheets. In certain embodiments, a photovoltaic module is fabricated without a back encapsulant layer, and the back sealing sheet is supported by the structural bond. The structural bond may also be used as a moisture barrier in addition or instead of an edge seal. The structural bond material can include a silicone-based polymer, which provides good adhesive and UV resistance properties. The structural bond may be formed by a structural bonding material that is dispensed around the photovoltaic cells. In certain embodiments, the material contacts at least a portion of the cells to provide mechanical support to the cells.

In certain embodiments, a photovoltaic module includes a front sealing sheet (i.e., a transparent light incident sheet), a back sealing sheet, one or more interconnected photovoltaic cells disposed between the two sheets, an encapsulant disposed between the front sheet and the cells, and a structural bonding material forming a structural bond between the two sheets. The portion of the front and back sheets extending outside of the cells may be referred to as a perimeter sealing area. Some or all of the structural bonding material is positioned in the perimeter sealing area. However, some material may be positioned outside of the perimeter sealing area, for example, between the back sealing sheet and the cells. In certain embodiments, a perimeter sealing area surrounds the photovoltaic cells. The structural bonding material supports the back sheet with respect to the front sheet and in certain embodiments, directly with respect to the cells. That is, the structural bonding material maintains the relative positions of the back sealing sheet and the front sealing sheet such that the two sheets do not move with respect to each other at least in the area of bonding, e.g., the sealing area. In certain embodiments, a substantially constant gap set by the structural bonding material and/or relative positions of the sheets' edges is maintained. In certain embodiments, the structural bonding material is flexible and allows some minimal motion between the two sealing sheets. For example, the two sealing sheets and/or photovoltaic cells may have different coefficients of thermal expansion, and the structural bonding material accommodates these differences during temperature swings without compromising mechanical integrity and/or other properties of the photovoltaic module.

In certain embodiments, a structural bonding material includes a silicone based polymer. A structural bonding material may have a pull-off strength of at least about 2 MPa when it forms a structural bond between the front and back sealing sheets. In the same or other embodiments, a structural bonding material has a lap shear strength of at least about 1 MPa between the two sealing sheets. The material may also have an elongation-at-break value of at least about 200%.

In certain embodiments, an average thickness of the structural bonding material in the sealing area between the two sheets is between about 5 mils and 100 mils. The material may form a strip in the sealing area surrounding the cells that is between about 0.1 inches and 2 inches wide. In certain embodiments, a structural bonding material forms a continuous strip in the sealing area substantially surrounding the photovoltaic cells. This continuous strip may provide sealing functionality as well as mechanical support to the back sheet as mentioned above. For example, a structural bonding material may have a water vapor transmission rate (WVTR) of less than about 10⁻² g/m²-day to prevent moisture from getting inside the module.

In certain embodiments, a module further includes an edge seal disposed between the front sealing sheet and the back sealing sheet in or next to the sealing area. An edge seal provides moisture and/or gas barrier functions. An edge seal may include butyl-rubber and/or a desiccant. In certain embodiments, an edge seal is positioned further away from the photovoltaic cells than the structural bonding material. In other embodiments, an edge seal is positioned closer to the cells than the structural bonding material.

A structural bonding material may be a UV resistant material. In certain embodiments, a transparent front sealing sheet includes a light barrier positioned at least next to the structural bonding material and configured to protect the material from direct light exposure. In the same or other embodiments, a front sealing sheet includes a glass sheet. A back sealing sheet may likewise includes a glass sheet. In other embodiments, a back sheet includes a flexible sheet. Inside surfaces of one or both sheets (i.e., one or both surfaces facing the structural bonding material) may be pretreated to improve adhesion of the sheets to the bonding material.

In certain embodiments, no encapsulant is disposed between the back sheet and the cells. In certain of these embodiments, the back sheet is supported substantially by the structural bond. The back sheet may be in direct contact with the cells. In some embodiments, a partial back encapsulant is provided covering only a portion of the cells' back surface. This encapsulant helps the structural bonding material support the back sealing sheet. In certain embodiments, photovoltaic cells are Copper-Indium-Gallium-Selenide (CIGS) cells. A photovoltaic module may be a frameless module.

Also provided are methods of fabricating a photovoltaic module containing structural bonding materials. In certain embodiments, a method involves providing a first sealing sheet that has an internal surface and a sealing area and dispensing a structural bonding material onto that surface in the sealing area. The method may proceed with assembling a stack that includes the first sealing sheet having the structural bonding material on its internal surface; a second sealing sheet that contacts the structural bonding material; and an encapsulant. The encapsulant is disposed between the photovoltaic cells and a front light-incident sheet, which may be the first sheet or the second sheet. In certain embodiments, dispensing a structural bonding material involves applying a tape and/or dispensing a paste (e.g., a thixotropic liquid) onto the internal surface of the first sheet in the sealing area. In certain embodiments, the assembled stack includes a first sealing sheet having the structural bonding material on its internal surface; a second sealing sheet that contacts one or more interconnected cells positioned between the two sealing sheets as well as the structural bonding material; and an encapsulant.

In certain embodiments, a process also involves curing the structural bonding material to form a structural bond between the first sheet and the second sheet. Curing may involve heat curing, moisture curing, and/or UV curing. In certain embodiments, assembling a stack involves laminating the stack prior to curing the structural bonding material. In certain embodiments, a process also involves, prior to, during or post assembly of the stack, dispensing a sealing material in addition to the structural bonding material, onto the internal surface of the first sealing sheet in the sealing area to form an edge seal.

These and other aspects of the invention are described further below with reference to the figures.

### BRIEF DESCRIPTION OF THE DRAWINGS

FIG. 1A is a schematic side view of a photovoltaic module including a structural bonding material in accordance with certain embodiments.

FIG. 1B is a schematic top view of a portion of a photovoltaic module showing a sealing area surrounding the photovoltaic cells of the module in accordance with certain embodiments.

FIG. 2 is a schematic representation of a photovoltaic module including a structural bonding material and an edge seal in accordance with certain embodiments.

FIG. 3 is a schematic representation of a photovoltaic module including a structural bonding material and an edge bracket in accordance with certain embodiments.

FIG. 4, is a schematic representation of a photovoltaic module including a structural bonding material and a light blocking feature in accordance with certain embodiments.

FIG. 5 is a schematic representation of a portion of a photovoltaic module illustrating a structural bonding material positioned in between the photovoltaic cells and back sealing sheet in accordance with certain embodiments.

FIG. 6 is a process flowchart corresponding to one example of a technique for fabricating a photovoltaic module including a structural bonding material.

### DETAILED DESCRIPTION OF EXAMPLE EMBODIMENTS

In the following description, numerous specific details are set forth in order to provide a thorough understanding of the present invention. The present invention may be practiced without some or all of these specific details. In other instances, well known process operations have not been described in detail to not unnecessarily obscure the present invention. While the invention will be described in conjunction with the specific embodiments, it will be understood that it is not intended to limit the invention to the embodiments.

### Introduction

A typical photovoltaic module includes one or more photovoltaic cells positioned in between two sealing sheets i.e., a front light-incident sheet and a back sheet. These sheets provide environmental and mechanical protection to the cells. The sheets may be attached to the cells with encapsulant layers, which also fill voids inside the module. Conventional photovoltaic modules have two encapsulant layers, i.e., one layer positioned between the front light-incident sheet and the cells and another layer positioned between back sheet and the cells. Each encapsulant layer adds to material and processing costs and makes the module heavier.

Embodiments described herein provide a photovoltaic module having only one encapsulant layer, positioned between the front light-incident sheet and the cells. In certain embodiments, the modules include a specially configured structural bond. The bond may partially or fully support the back sealing sheet. Furthermore, the structural bond may seal the module at least in the sealing area together with an additional edge seal or even without an additional edge seal. In certain embodiments, the structural bond is formed by a structural bonding material positioned at least partially in the sealing area between the two sealing sheets. The material forms adhesive (e.g., chemical and/or physical) bonds with both sheets.

As indicated above, the structural bond provides mechanical support to module components such as one or more sealing sheets. As used herein with respect to various module components, the term “supporting with respect to,” (e.g., the back sealing sheet and front sealing sheet are “supported with respect to each other”) refers to maintaining relative positions between the module components such that the two sheets are substantially immobile with respect to each other in one or more directions. In certain embodiments, the relative positions only in one or more directions is maintained with expansion or contraction allowed in one or more directions. In certain embodiments, the module components are substantially immobile with respect to each other in all directions.

Also as indicated above, the structural bond may provide a sealing function that protects the cells from the environment and moisture ingress. For example, a structural bonding material may have a water vapor transmission rate (WVTR) of less than about 10⁻² g/m²/day or, more particularly, less than about 10⁻³ g/m²/day to prevent moisture ingress in between the sealing sheets.

In some embodiments, a module includes a back encapsulant layer. However, this layer may be less relied on for mechanical support and/or sealing functions than some conventional back encapsulant layers. For example, a back encapsulant layer may only partially cover the cells' surface and leave significant voids in between the cells and the back sealing sheet. In certain embodiments, a structural bonding material is designed to replace or at least complement functions of a conventional back encapsulant layer.

Structural bond features can be used in either frameless or framed photovoltaic modules. A frame provides additional structural support to the two sealing sheets and can complement functions of the structural bond and can be used for particularly large and heavy back sealing sheets. However, frames are costly. Some structural bonds are designed to be sufficiently strong to support a back sealing sheet without a need of a frame. In certain embodiments, a module may include one or more brackets (instead of a complete perimeter frame) that help supporting the back sealing sheet and, in more specific embodiments, can be used as module mounting features.

Photovoltaic modules having novel structural bonding features can have flexible sealing sheets, rigid sealing sheets, or a combination of both. For example, a structural bonding material may be disposed between two rigid glass sheets or between a rigid glass sheet and a flexible polyethylene terephthalate (PET) sheet. Various examples of sealing sheets are described below. In certain embodiments, both sealing sheets extend outside laterally of the photovoltaic cells' perimeter. This extension is referred to as a sealing area and is used for dispensing a structural bonding material. In certain embodiments, the material substantially surrounds the photovoltaic cells.

A structural bonding material may be a silicone-based polymer. Some examples include the following material available from Dow Corning in Midland, Mich.: silicone adhesives (part numbers 3-1595 and 3-1595HP), thixotropic adhesive (part number 3-6265), silane and siloxane based adhesives (part number 4-8012), primer-less silicone adhesive (part number 866), heat cured one part adhesive (part number SE1771), thixotropic fast low temperature cure adhesive (part number EA-6054), two part translucent heat cure adhesive (part number SE1700), Sylgard® 577 primer-less silicone adhesive, PV-804 Neutral Sealant, and two-part controlled-volatility (CV) grade adhesive (part number SE1720). Other thermoset/reactive adhesives based on epoxies, acrylates and polyurethanes may also be used.

### Photovoltaic Module and Structural Bond Examples

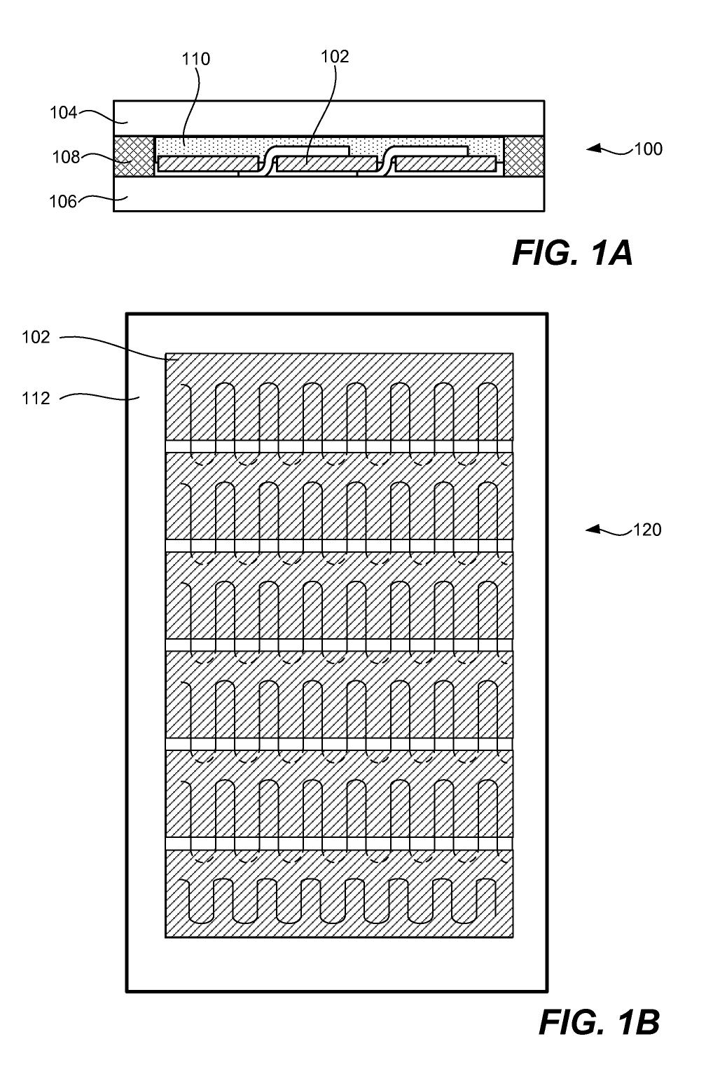

Structural bond features of various embodiments will now be described in the context of certain photovoltaic module structures and fabrication techniques. FIG. 1A is a schematic representation of a photovoltaic module 100 with a structural bonding material 108 in accordance with certain embodiments. A module 100 includes one or more interconnected photovoltaic cells 102 positioned between a front light-incident sealing sheet 104 and a back sealing sheet 106. As mentioned above, these sheets (104 and 106) are used for environmental protection and/or mechanical support of cells 102. An encapsulant layer 110 is provided between front sheet 104 and cells 102 for mechanically interconnecting these two elements and substantially filling any voids there-between. Having fewer voids improves light transmission and the sealing properties of the module. The two sealing sheets 104 and 106 are bonded together with structural bonding material 108. In certain embodiments further described below, a structural bonding material can also bond to other elements, such as photovoltaic cells 102.

Various materials can be used for front sheet 104 and back sheet 106. Such materials should provide protective and support functions. Sealing sheets can be made from rigid and/or flexible materials. For example, in certain embodiments both front and back sheets are made from rigid glass sheets. In another example, a front sheet is made from a rigid glass sheet, while a back sheet is made from a flexible sheet. In yet another example, both sealing sheets are flexible. Examples of rigid materials include window glass, plate glass, silicate glass, low iron glass, tempered glass, tempered CeO-free glass, float glass, colored glass, and the like. In certain embodiments, one or both of the front and back sheets are made from or include polymer materials. Examples of polymer materials, which could be rigid or flexible, include polyethylene terephthalate), polycarbonate, polypropylene, polyethylene, polypropylene, cyclic polyloefins, norbornene polymers, polystyrene, syndiotactic polystyrene, styrene-acrylate copolymers, acrylonitrile-styrene copolymers, poly(ethylene naphthalate), polyethersulfone, polysulfone, nylons, poly(urethanes), acrylics, cellulose acetates, cellulose triacetates, cellophane, vinyl chloride polymers, polyvinylidene chloride, vinylidene chloride copolymers, fluoropolymers, polyvinyl fluoride, polyvinylidene fluoride, polytetrafluoroethylene, ethylene-tetrafluoroethylene copolymer, and the like. A thickness of the sealing sheet may be between about 1 millimeter and about 15 millimeters or, more particularly, between about 2.5 millimeters and about 10 millimeters, for example, about 3 millimeters or about 4 millimeters. In certain embodiments, sealing sheets have various surface treatments and features, such as UV filters, anti-reflective layers, surface roughness, protective layers, moisture barriers, or the like. For example, front sheet 104 and/or back sheet 106 may have their internal surfaces partially treated to improve adhesion to structural bonding material 108. In the same or other embodiments, front sheet 104 has a light blocking feature protecting structural bonding material 108 from direct sunlight. These and other examples are further described below.

Photovoltaic cells 102 may be one of the following types of solar cells: microcrystalline silicon, amorphous silicon, cadmium telluride (CdTe), copper indium gallium selenide (GIGS), copper indium selenide (CIS), gallium indium phosphide (GaInP), gallium arsenide (GaAs), dye-sensitized solar cells, and organic polymer solar cells. Photovoltaic cells may include light absorbing materials sandwiched between electrical contact layers. In particular embodiments, cells 102 are CIGS cells. Cells 102 may have a transparent conductive layer formed over the light absorbing and other layers as a contact layer on the light-incident side. This conductive layer may include various transparent conductive oxides (TCOs), such as tin oxide, fluorine-doped tin oxide, indium tin oxide, doped or un-doped zinc oxide including aluminum, fluorine, gallium, or boron dopants, indium zinc oxide, cadmium sulfide, and cadmium oxide. A current collector may be provided over the transparent conductive oxide for collecting an electrical current generated by the semiconductor junction. A current collector may include a conductive epoxy, a conductive ink, a metal, (e.g., copper, aluminum, nickel, or silver or alloys thereof in the form of a wire network or metallic tabs), a conductive glue, or a conductive plastic. The light absorbing layers may be formed on a metal-containing substrate that provides mechanical support and electrical conductivity functions to the cell. This metal containing substrate may made from stainless steel, aluminum, copper, iron, nickel, silver, zinc, molybdenum, titanium, tungsten, vanadium, rhodium, niobium, chromium, tantalum, platinum, gold, or any alloys thereof.

In certain embodiments further described in the context of FIG. 5, photovoltaic cells 102 are in contact with a structural bonding material. In some of these embodiments, cells 102 may have surfaces that are at least partially treated. For example, a portion of a substrate that is in contact with a structural bonding material is treated to improve an adhesive bond between the structural bonding material and the substrate. A treatment may involve application of adhesives, primers (e.g., silanes or polyallylamine-based materials), flame treatments, plasma treatments, electron beam treatments, oxidation treatments, corona discharge treatments, chemical treatments, chromic acid treatments, hot air treatments, ozone treatments, ultraviolet light treatments, sand blast treatments, solvent treatments, and the like as well as combinations thereof.

Photovoltaic module 100 includes at least one encapsulant layer 110 positioned between front sealing sheet 104 and cells 102. In certain embodiments, this is the only encapsulant layer provided in the module with no encapsulant layer between back sealing sheet 106 and cells 102. In some embodiments, an encapsulant layer (not shown) is also provided between back sealing sheet 106 and cells 102. Examples of encapsulant materials include polyolefins (e.g., polyethylene, polypropylene, ethylene and propylene copolymer, polyethylene ionomer, ethylene and ethylene vinyl acetate (EVA) copolymer, crosslinked polyethylene), polyesters (e.g., polyethylene terephthalate, polyethylene naphthalate, polytrimethylene terephthalate, polybutylene terephthalate, polycarbonate), polyamides (e.g., nylon), acrylates (e.g., polymethyl methacrylate, polymethyl acrylate, polyethylene-co-butyl acrylate) ionomers), elastomers (e.g. thermoplastic polyurethane, polybutadiene, silicone, polyisoprene, natural rubber), fluoropolymers (e.g., polyvinylidene fluoride, polyvinyl fluoride, polytetrafluoroethylene), biodegradable polymers (e.g., polylactic acid, polyhydroxybutyrate, polyhydroxyalkanoate), and vinyl polymers (e.g., polyvinyl chloride, polyvinyl acetate, polystyrene). Other examples include various thermoplastic resins, thermoset resins, epoxy resins, plastomers and/or any other suitable chain-like molecules. In specific embodiments, an encapsulant is polyethylene, in particular, linear low density polyethylene. Examples also include SURLYN® thermoplastic ionomeric resins (e.g., PV4000, PV5200, PV5300, PV8600 or equivalent) and SENTRY GLASS® laminate inter-layers available from DuPont in Wilmington, Del. Additional examples include GENIOMER® 145 thermoplastic silicone elastomers available from Wacker Chemie in Munich, Germany. In specific embodiments, an encapsulant includes a silicone-based amorphous thermoplastic material. Furthermore, an encapsulant may include a thermoplastic olefin (TPO). An average thickness of the encapsulant layer may vary between 2 mils and 60 mils or, more particularly, between 2 mils and 16 mils or, in other embodiments, between about 16 mils and 60 mils.

As shown in FIG. 1A, front sealing sheet 104 and back sealing sheet 106 typically extend laterally outside of the area defined by cells 102. The extension area of each sheet is referred to as a sealing area of that sheet. For example, a distance between an edge of a sealing sheet and cells may be between about 0.25 inches and 5 inches or, more particularly, between about 0.5 inches and 2 inches. This distance may define the width of the sealing area of that sheet. According to various embodiments, a sealing area width may be substantially constant or vary around the perimeter of the cell area. The extension area where the sealing areas of the front and back sheets overlap is referred to as a perimeter sealing area of the module. In many embodiments, the sealing areas of the front and back sheets are co-extensive with each other, and hence the perimeter sealing area of the module. The perimeter sealing area is the area in which a perimeter seal may be formed around the cells of the module, although in certain embodiments, the seal does not occupy the entire width of the perimeter sealing area.

FIG. 1B is a schematic top view of a portion 120 of a photovoltaic module showing a sealing area 112 surrounding photovoltaic cells 102 of the module in accordance with certain embodiments. As shown, the sealing area 112 extends completely around the cells. A structural bonding material may form a substantially continuous strip around cells, which may also be used for sealing purposes. In certain embodiments, a structural bonding material disposed in discrete patches in the sealing area along with one or more additional components is used for sealing the module. An example of an additional sealing component is an edge sealing material such as a butyl-rubber based desiccant.

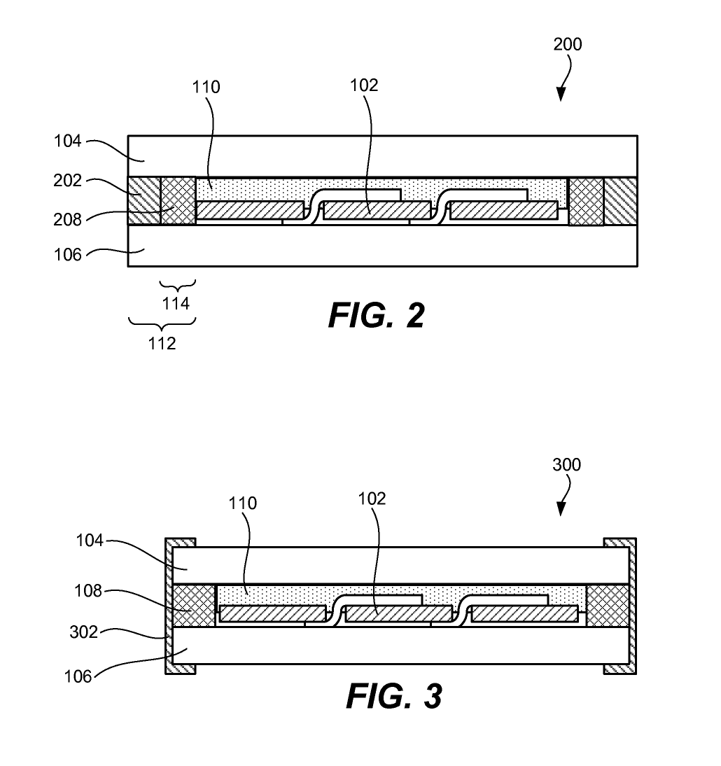

A structural bonding material may occupy the entire perimeter sealing area or a portion of the perimeter sealing area. The area occupied by the structural bonding material is referred to as a bonding area. For example, in FIG. 2, perimeter sealing area 112 is shared by an edge seal 202 and a structural bonding material 208. Bonding area 114 of sheet 106 is indicated. In certain embodiments, a portion of the structural bonding material may occupy an area outside the sealing area of a sheet. For example, a portion of the structural bonding material may underlay a portion of the cell area on the cell's backside. In many embodiments, the width of the sealing area and/or bonding area of the front sheet is substantially the same as that of the back sealing sheet, though in some embodiments, they may be different.

In general, a structural bonding material makes at least some contact with both front sealing sheet 104 and back sealing sheet 106 in their respective sealing areas. This configuration establishes structural support between the two sheets and, in certain embodiments, provides sealing functions. In certain embodiments, as shown in FIG. 5, a structural bonding material 502 extends outside of the perimeter sealing area 112 and in between cells 102 and back sealing sheet 106. In this configuration, the structural bonding material may also provide direct structural support to cells 102.

### Structural Bond and Structural Bond Material Examples

In certain embodiments, specially designed adhesive materials are used as structural bonding materials for bonding two sealing sheets in photovoltaic modules. Adhesives used as structural bonding materials may be heat cured adhesives, UV cured adhesives, and/or moisture cured adhesives. A structural bonding material may include a two-component or a single-component adhesive. Examples of structural bonding materials include silicone based adhesives. Specific examples include the following adhesives available from Dow Corning in Midland, Mich.: silicone adhesive (part numbers 3-1595 and 3-1595HP), thixotropic adhesive (part number 3-6265), silane and siloxane based adhesives (part number 4-8012), primer-less silicone adhesive (part number 866), heat cured one part adhesive (part number SE1771), thixotropic fast low temperature cure adhesive (part number EA-6054), two part translucent heat cure adhesive (part number SE1700), Sylgard® 577 primer-less silicone adhesive, PV-804 neutral cure or two-part controlled-volatility (CV) grade adhesive (part number SE1720). Other thermoset/reactive adhesives based on epoxies, acrylates and polyurethanes may also be used.

In certain embodiments, a structural bonding material has a pull-off strength of at least about 2 MPa after it forms a structural bond between the front and back sealing sheets. In specific embodiments, the pull-off strength is at least about 3 MPa, at least about 4 MPa, or at least about 5 MPa. High pull-off strength values may be used for structural bonding materials supporting heavy back sealing sheets, for example, sealing sheets that are large in size and/or made from thick and/or heavy materials (e.g., glass sheets). In the same or other embodiments, a structural bonding material has a lap shear strength of at least about 1 MPa between the two sheets or, more particularly, at least about 2 MPa or at least about 3 MPa. Furthermore, a structural bonding material may have an elongation-at-break value of at least about 200% or, more particularly, at least about 400% or at least about 750%.

In certain embodiments, an average thickness of the structural bonding material in between the sealing areas of the two sheets is between about 0.1 mils and 100 mils or, more particularly, between about 0.5 mils and 25 mils. In embodiments in which the structural bonding material directly contacts the front and back sheets, this thickness is equivalent to the distance between the front and back sheets. A thicker material may be needed between two rigid sealing sheets (i.e., rigid glass plates) in order to accommodate for thicknesses of photovoltaic cells, at least one encapsulation layer, and other features positioned in between the two rigid sealing sheets. However, thicker structural bonds may not be sufficiently strong and/or may be more susceptible to moisture permeation. In certain embodiments, a structural bond is sufficiently thin to serve as a moisture barrier, as further described below. In certain embodiments, the two sealing sheets are in direct contact with each other in a sub-area of the sealing area with very little or substantially no structural sealing material present in between the two sealing sheets in this sub-area. For example, two polymer sealing sheets may be heat sealed together in addition to being bonded together with a structural bonding material.

A structural bonding material may form a strip in the perimeter sealing area of a sheet that is between about 0.1 inches and 2 inches wide or, more particularly, between about 0.25 inches and 1 inch. In certain embodiments, a structural bonding material forms a substantially continuous strip in the sealing areas of the sheets surrounding the cells. It should be noted that this substantially continuous strip may be interrupted by electrical connectors and other module components that do not interfere with the structural bonding and, in certain embodiments, sealing properties of the structural bond. For example, interruptions of a substantially continuous strip may account for less than 1% of the strip's total length or, more particularly, less than about 0.1%.

As noted above, a structural bonding material may also be used for sealing purposes in addition to (e.g., as shown in FIG. 2) or instead of (e.g., as shown in FIG. 1A) an edge seal. For example, a structural bonding material may have a water vapor transmission rate (WVTR) of less than about 10⁻² g/m²/day or, more particularly, less than about 10⁻³ g/m²/day to prevent moisture from ingressing into the module. If a structural bonding material is used instead of an edge seal, then the structural bonding material should form a substantially continuous strip around the cells as described above.

FIG. 2 is a schematic representation of a photovoltaic module 200 including a structural bonding material 208 and an edge seal 202 in accordance with certain embodiments. Similar to structural bonding material 208, edge seal 202 is also positioned in perimeter sealing area 112. Edge seal 202 may include butyl-rubber or other suitable sealing materials. In certain embodiments, an edge seal includes a desiccant or other moisture capturing materials and/or features. Edge seal 202 may be positioned further away from photovoltaic cells 102 than structural bonding material 208 as shown in FIG. 2. In this configuration, edge seal 202 provides some environmental protection to structural bonding material 208, which may be particularly suitable for structural bonding materials that are sensitive to moisture and other environmental impacts. In other embodiments (not shown), an edge seal is positioned closer to the cells than the structural bonding material.

In certain embodiments, a structural bonding material is used in a frameless module. As mentioned above, frameless modules are lighter and generally less expensive to manufacture. The bonding material is sufficiently strong in these configurations to support both sealing sheets with respect to each other without a need for an external frame. In other embodiments, a module has a frame supporting the two sealing sheets. FIG. 3 is a schematic representation of a side cross-sectional view of a photovoltaic module 300 including a structural bonding material 108 and a frame 302 in accordance with certain embodiments. For example, U-shaped channels may be snugly fit over edges of the module to provide additional mechanical support and/or sealing to the module. In certain embodiments, a module has a set of U-shaped brackets positioned over edges of the module instead of a complete frame surrounding the entire perimeter of the frame. These brackets may be used for mounting the module on various module supporting structures, e.g., rooftops. Frames or brackets may be made from aluminum, steel, or any other suitable materials. They can be positioned on a photovoltaic module during fabrication or installation.

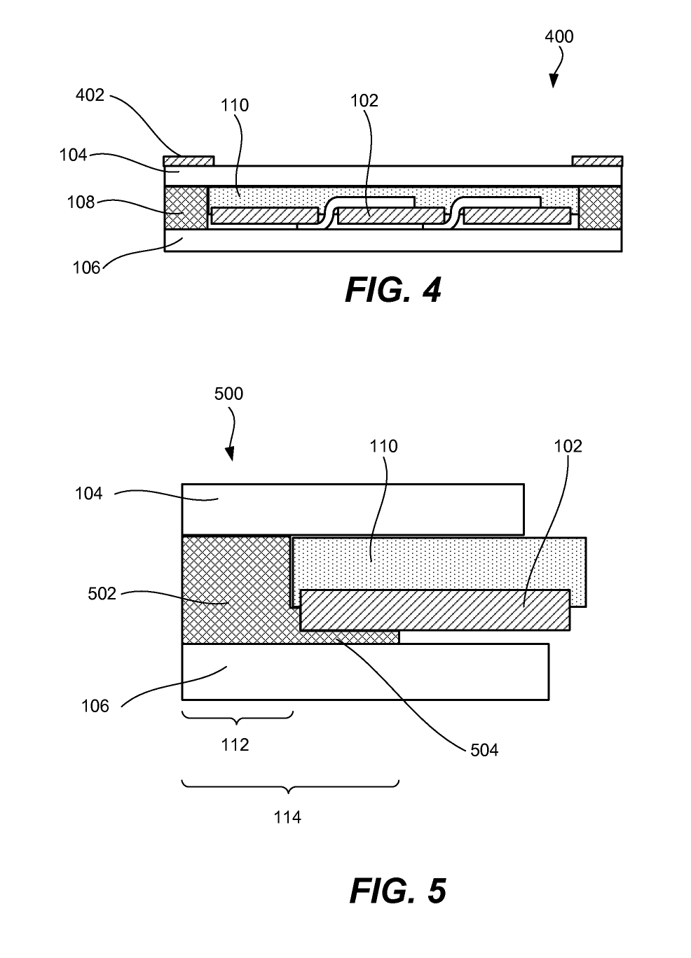

A structural bonding material is positioned under a transparent light-incident front sealing sheet and may be exposed to sunlight during operation of the module. In certain embodiments, various UV and light resistant adhesives are used to ensure reliable performance of the structural bond over the lifetime of the module. In the same or other embodiments, a structural bonding material is at least partially protected from direct sun light by one or more light blocking features. FIG. 4 is a schematic representation of a photovoltaic module 400 including a structural bonding material 108 and a light blocking feature 402 in accordance with certain embodiments. Light blocking feature 402 may be may be made from an opaque material, e.g., a thin metal sheet, opaque plastic sheet, a reflective coating, or any other suitable structure. It may be positioned over the external surface of the front sealing sheet (as shown in FIG. 4) or between the front sealing sheet 104 and structural bonding material 108, e.g., abutting the internal surface. Light blocking feature 402 is positioned such that it does not block photovoltaic cells 102 from sunlight. Light blocking feature 402 may be provided only above the sealing area of sheet 104. In certain embodiments, a light blocking feature is integrated into a frame or a bracket described above in the context of FIG. 3.

A module having a structural bonding material may be fabricated and operated without a back encapsulant layer. In this configuration, the back sealing sheet may be at least partially supported by a structural bonding material. In certain embodiments, a structural bonding material is also used to provide some mechanical support to photovoltaic cells. In these embodiments, a portion of the structural bonding material may extend outside of the sealing area to make contact with the photovoltaic cells. In more specific embodiments, a portion of the structural bonding material extends in between one or more cells and the back sheet. FIG. 5 is a schematic representation of a portion 500 of a photovoltaic module illustrating an extension 504 of structural bonding material 502 positioned between photovoltaic cells 102 and back sealing sheet 106 in accordance with certain embodiments. Extension 504 extends beyond the sealing area 112 towards the module interior and provides a direct bond between cells 102 and back sealing sheet 106. It may be used, at least in part, to fill the gap between these elements.

### Processing

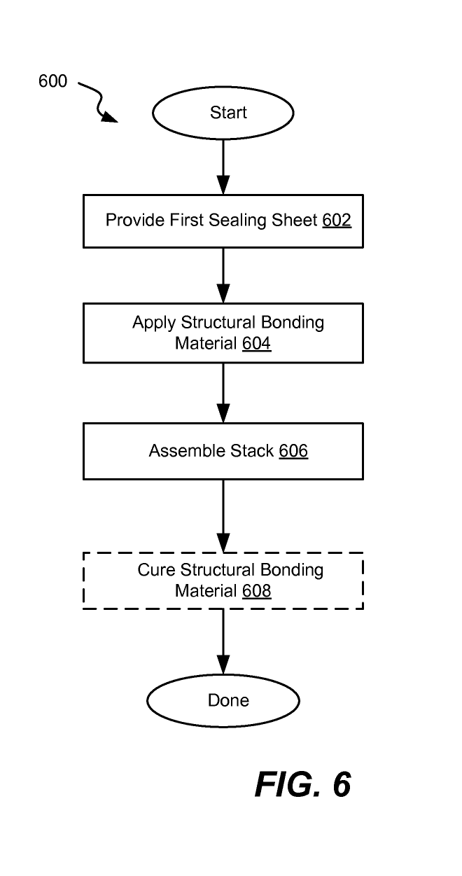

Provided also are methods of fabricating a photovoltaic module containing structural bonding materials. FIG. 6 is a process flowchart 600 corresponding to one example of such methods. At 602 a first sealing sheet is provided for processing. The first sealing sheet may be either a front light-incident sealing sheet or a back sealing sheet. Various examples of sealing sheets are described above. The provided sealing sheet has an internal surface and a sealing area. The internal surface is internal with respect to the module, such that it faces photovoltaic cells. At 604 a structural bonding material is applied on the internal surface to the sealing area. Application may involve distributing an adhesive in the area or applying a tape containing the bonding material. Examples of structural bonding materials are described above. Application methods will generally depend on the adhesive type. For example, if a two-component structural bonding material is used, then operation 604 may also involve premixing the two components prior to applying the premixed material onto a surface. In certain embodiments, a structural bonding material is applied after a first and second sealing sheets are assembled together (e.g., after the two sheets are laminated to each other with photovoltaic cells positioned in between the two sheets). The structural bonding material may be positioned outside of an edge seal.

In certain embodiments, an internal surface area is treated prior to application of the structural bonding material, for example, to improve adhesion of the material to the sealing sheet surface. Such treatments may involve priming (e.g., applying silanes and/or poly(allyl amine) based materials), flame treatments, plasma treatments, electron beam treatments, oxidation treatments, corona discharge treatments, chemical treatments, chromic acid treatments, hot air treatments, ozone treatments, ultraviolet light treatments, sand blast treatments, solvent treatments, and the like as well as combinations thereof.

At 606, a stack including the first sealing sheet having structural bonding material dispensed on its internal surface, a second sealing sheet contacting the structural bonding material, and interconnected photovoltaic cells positioned between the first and the second sealing sheets, is assembled. The stack typically includes at least one encapsulant layer positioned between the front light incident sealing sheet (which could be either the first sheet or the second sheet) and the photovoltaic cells. In certain embodiments, a stack has two encapsulant layers positioned on either side of the photovoltaic cells.

During the stack assembly, the structural bonding material contacts at least a portion of the sealing area of the second sealing sheet. In certain embodiments, operation 606 may involve lamination of the stack, e.g.; by applying pressure and/or vacuum conditions. For example, stack components may be first positioned in a lamination chamber. Before the second sheet contacts the structural bonding material, the chamber is out-gassed and brought to a relatively low pressure level. The second sheet then contacts the structural bonding material and the pressure inside the chamber is then increased, which in turn compresses the stack and the perimeter sealing area helping to form a structural bond. The process may involve an optional curing operation 608 for curing a structural bonding material applied in operation 604 to form a structural bond between the first sheet and the second sheet. Curing may involve heat curing, moisture curing, and/or UV curing.

### CONCLUSION

Although the foregoing invention has been described in some detail for purposes of clarity of understanding, it will be apparent that certain changes and modifications may be practiced within the scope of the appended claims. It should be noted that there are many alternative ways of implementing the processes, systems, and apparatus of the present invention. Accordingly, the present embodiments are to be considered as illustrative and not restrictive, and the invention is not to be limited to the details given herein.

What is claimed is:

1. A frameless photovoltaic module comprising:
a transparent front sealing sheet comprising a glass sheet;
a back sealing sheet comprising a glass sheet;
a plurality of interconnected photovoltaic cells disposed between the transparent front sealing sheet and the back sealing sheet, wherein the transparent front sealing sheet and the back sealing sheet extend beyond the plurality of interconnected photovoltaic cells and form a perimeter sealing area surrounding the plurality of interconnected photovoltaic cells;
an encapsulant disposed between the transparent front sealing sheet and the plurality of interconnected photovoltaic cells; and
a structural bonding material comprising a UV resistant silicone-based adhesive disposed in the perimeter sealing area and forming a structural bond between the transparent front sealing sheet and the back sealing sheet, wherein the structural bonding material provides mechanical support to the back sealing sheet,
wherein no encapsulant is disposed between the back sealing sheet and the plurality of interconnected photovoltaic cells.

2. A photovoltaic module comprising:
a transparent front sealing sheet;
a back sealing sheet;
a plurality of interconnected photovoltaic cells disposed between the transparent front sealing sheet and the back sealing sheet, wherein the transparent front sealing sheet and the back sealing sheet extend beyond the plurality of interconnected photovoltaic cells and form a perimeter sealing area surrounding the plurality of interconnected photovoltaic cells;
an encapsulant disposed between the transparent front sealing sheet and the plurality of interconnected photovoltaic cells; and
a structural bonding material disposed in the perimeter sealing area and forming a structural bond between the transparent front sealing sheet and the back sealing sheet, wherein the structural bonding material provides mechanical support to the back sealing sheet.

3. The photovoltaic module of claim 2, wherein the structural bonding material comprises a silicone-based adhesive, an epoxy, an acrylate adhesive, and/or a polyurethane adhesive.

4. The photovoltaic module of claim 2, wherein the structural bonding material has a pull-off strength of at least about 2 MPa between the transparent front sealing sheet and the back sealing sheet.

5. The photovoltaic module of claim 2, wherein the structural bonding material has a lap shear strength of at least about 1 MPa between the transparent front sealing sheet and the back sealing sheet.

6. The photovoltaic module of claim 2, wherein the structural bonding material has an elongation-at-break value of at least about 200%.

7. The photovoltaic module of claim 2, wherein an average thickness of the structural bonding material in the perimeter sealing area is between about 5 mils and 100 mils.

8. The photovoltaic module of claim 2, wherein an average width of a strip formed by the structural bonding material in the perimeter sealing area is between about 0.1 inches and 2 inches.

9. The photovoltaic module of claim 2, wherein the structural bonding material forms a substantially continuous strip in the perimeter sealing area surrounding the plurality of interconnected photovoltaic cells.

10. The photovoltaic module of claim 2, wherein the structural bonding material has a water vapor transmission rate (WVTR) of no more than about 10⁻² g/m²/day.

11. The photovoltaic module of claim 2, wherein the transparent front sealing sheet comprises a light barrier positioned at least above the structural bonding material.

12. The photovoltaic module of claim 2, wherein the structural bonding material is UV resistant.

13. The photovoltaic module of claim 2, wherein a portion of the structural bonding material extends outside of the perimeter sealing area towards the plurality of interconnected photovoltaic cells and partially positioned in between the plurality of interconnected photovoltaic cells and the back sealing sheet.

14. The photovoltaic module of claim 2, further comprising a edge seal disposed between the transparent front sealing sheet and the back sealing sheet in or next to the perimeter sealing area.

15. The photovoltaic module of claim 14, wherein the edge seal comprises butyl-rubber and a desiccant.

16. The photovoltaic module of claim 14, wherein the edge seal is positioned further away from the plurality of interconnected photovoltaic cells than the structural bonding material.

17. The photovoltaic module of claim 2, wherein the transparent front sealing sheet comprises a glass sheet or a flexible sheet.

18. The photovoltaic module of claim 2, wherein at least a portion of a surface of the transparent front sealing sheet facing the structural bonding material is pretreated to improve adhesion of the transparent front sealing sheet to the structural bonding material.

19. The photovoltaic module of claim 2, wherein the back sealing sheet comprises a glass sheet.

20. The photovoltaic module of claim 2, wherein the back sealing sheet comprises a flexible sheet.

21. The photovoltaic module of claim 2, wherein no encapsulant is disposed between the back sealing sheet and the plurality of interconnected photovoltaic cells.

22. The photovoltaic module of claim 2, wherein the back sealing sheet is in direct contact with the plurality of interconnected photovoltaic cells.

23. The photovoltaic module of claim 2, wherein the plurality of interconnected photovoltaic cells comprises Copper-Indium-Gallium-Selenide (CIGS) cells.

24. The photovoltaic module of claim 2, wherein the photovoltaic module is a frameless photovoltaic module.

25. A method of fabricating a photovoltaic module comprising:
(a) providing a first sealing sheet comprising an internal surface and a sealing area;
(b) dispensing a structural bonding material onto the internal surface of the first sealing sheet in the sealing area; and
(c) assembling a stack comprising:
the first sealing sheet,
the structural bonding material;
a second sealing sheet contacting the structural bonding material,
a plurality of interconnected photovoltaic cells positioned between the first and the second sealing sheet,
an encapsulant disposed either between the plurality of interconnected photovoltaic cells and the first sheet or between the plurality of interconnected photovoltaic cells and the second sheet,
wherein the structural bonding material comes into contact with the second sealing sheet during assembly.

26. The method of claim 25, wherein dispensing the structural bonding material comprises applying a tape and/or dispensing a paste onto the internal surface of the first sealing sheet in the sealing area.

27. The method of claim 25, further comprising curing the structural bonding material to form a structural bond between the first sheet and the second sheet.

28. The method of claim 27, wherein curing the structural bonding material comprises one or more operations selected from the group consisting of heat curing, moisture curing, and UV curing.

29. The method of claim 27, wherein assembling the stack comprises laminating the stack prior to curing the structural bonding material.

30. The method of claim 25, further comprising, prior to, during, or post assembling the stack, dispensing a sealing material onto the internal surface of the first sealing sheet in the sealing area to form an edge seal.
